(19) United States
(12) Patent Application Publication
(10) Pub. No.: US 2024/0152330 A1
(43) Pub. Date: May 9, 2024

(54) K-CLUSTER RESIDUE NUMBER SYSTEM USING LOOK-UP TABLES WITH REDUCED DATA CAPACITY FOR ADDITION, SUBTRACTION, AND MULTIPLICATION OPERATIONS

(71) Applicant: Kneron Inc., San Diego, CA (US)

(72) Inventors: Oscar Ming Kin Law, San Diego, CA (US); Chun Chen Liu, San Diego, CA (US)

(73) Assignee: Kneron Inc., San Diego, CA (US)

(21) Appl. No.: 17/978,981

(22) Filed: Nov. 2, 2022

(51) Int. Cl. G06F 7/72; G06F 1/03

(52) U.S. Cl. CPC G06F 7/729; G06F 1/03

(57) ABSTRACT

A k-cluster residue number system has a processor and a memory. The processor is used to generate an addition and subtraction look-up table and a multiplication look-up table based on periodic behaviors of the modulo to compress the sizes of the addition and subtraction look-up table and the multiplication look-up table. The addition and subtraction look-up table has 2mᵢ cells for recording values from zero to (mᵢ−1) in an ascending order twice, wherein mᵢ is a coprime integer of a modular set of the k-cluster residue number system. The multiplication look-up table has S cells, where

$$S = ( \frac{{m}_{i}^{2} - 1}{4} ) .$$

### BACKGROUND OF THE INVENTION

### 1. Field of the Invention

The present invention is related to a k-cluster residue number system, and more particularly, to a memory-based k-cluster residue number system using look-up tables with reduced data capacity.

### 2. Description of the Prior Art

Edge artificial intelligence (AI) computing is an area of rapid growth, which integrates neural networks with the Internet of Things (IoT) together for computer vision, natural language processing, and self-driving car applications, it quantizes the floating-point number to fixed-point integer for inference operations. In-memory architecture is one of the important Edge AI computing platforms, which stacks the memory over the top of the logic circuits for Memory Centric Neural Computing (MCNC). The data is directly loaded from stacked memory to Processing Elements (PEs) for computation, it avoids loading the data from the external memory and minimizes data transfer. It significantly reduces the latency and speeds up the operations. The performance is further enhanced using Residue Number System (RNS), which fully utilizes the internal memory to store the data for integer operations.

Residue Number System (RNS) is a number system, which first defines the modular set and transforms the numbers to their integer remainders (also called residues) through modulo division, then performs the arithmetic operations (addition, subtraction, and multiplication) on the remainders only. For example, the modular set is defined as (7, 8, 9) with the numbers 13 and 17. The dynamic range is defined by the product of a modular set with the range 504. It first transforms the numbers to their residue through modulo operations 13→(6, 5, 4) and 17→(3, 1, 8), then performs addition and multiplication on residues only, (6, 5, 4)+(3, 1, 8)=(9, 6, 12)→(2, 6, 3), which is equal to 30. (6, 5, 4)*(3, 1, 8)=(18, 5, 32)→(4, 5, 5), which is equal to 221. Since the remainder magnitude is much smaller, it only requires simple logic for parallel computations.

For the sake of clarity, the dynamic range of the RNS may be defined as the following equation (1):

$$M = {\prod }_{i = 0}^{n} {m}_{i} \qquad ( 1 )$$

where:
M is the dynamic range of the RNS; and
mᵢ is the i^{th} modulus of the modular set (m₀, m₁, . . . , mₙ) of the RNS.

All the arithmetic operations of the RNS can be implemented using the memory lookup tables for parallel distributed computing. However, the memory requirement is the drawback of using lookup tables in the RNS. The required size of memory is dependent on the square of each modulus as well as the number of bits of the modulus, and can be presented as the following equation (2):

$$M e m = {\sum }_{i = 0}^{n} {m}_{i}^{2} \times {b}_{i} \qquad ( 2 )$$

where:
Mem is the required size of memory;
mᵢ is the i^{th} modulus; and
bᵢ is the number of bits of the i^{th} modulus.

For example, it chooses the RNS modular set as (15, 17) with the dynamic range M=15×17=2552. Since the first modulus (i.e., 15) has a 4-bit length and the second modulus (i.e., 17) has a 5-bit length, for all three arithmetic (i.e., addition, subtraction, and multiplication) operations, the total memory requirement is estimated to be 3×(15²×4+17²×5)=7035 bits. The area is too large compared with the logic gate design (e.g., the processing elements (PEs)) of the RNS.

### SUMMARY OF THE INVENTION

In an embodiment, a method for performing operations in a k-cluster residue number system comprises generating an addition and subtraction look-up table comprising 2mᵢ cells for recording values from zero to (mᵢ−1) in an ascending order twice, storing the addition and subtraction look-up table in a memory of the k-cluster residue number system, retrieving a value recorded in a cell at position Q of the addition and subtraction look-up table when performing an addition operation on two integers A and B, and retrieving a value recorded in a cell at position R of the addition and subtraction look-up table when subtracting an integer X by an integer Y. Where mᵢ is a coprime integer of a modular set of the k-cluster residue number system, Q=((A mod mᵢ)+(B mod mᵢ)), R=(X mod mi)−(Y mod mi)=(X mod mi)+(mi−(Y mod mi))=rx+(mi−ry)=(rx+ry′), rx is equal to (X mod mᵢ), ry is equal to (Y mod mᵢ), and ry′ is equal to (mᵢ−(Y mod mᵢ)).

In another embodiment, a method for generating a k-cluster residue number system comprises generating a multiplication look-up table for a coprime integer mᵢ of a modular set of the k-cluster residue number system, storing the multiplication look-up table in a memory of the k-cluster residue number system, and performing a multiplication operation on a multiplicand and a multiplicator using the multiplication look-up table. The coprime integer mᵢ is not 2, and the multiplication look-up table is composed of S cells,

$$S = ( \frac{{m}_{i}^{2} - 1}{4} ) .$$

The multiplication operation comprises determining whether a complement of the multiplicand is greater than or equal to the multiplicator; if it is determined that the complement of the multiplicand is greater than or equal to the multiplicator, performing a first procedure; if it is determined that the complement of the multiplicand is less than the multiplicator, performing a second procedure; and retrieving a value from the multiplication look-up table as a product of the multiplicand and the multiplicator according to a column entry and a row entry. The first procedure comprises the following steps: selecting the multiplicand as the column entry and the multiplicator as the row entry, and determining whether the column entry is greater than or equal to the row entry; if it is determined that the column entry is greater than or equal to the row entry, keeping the column entry and the row entry; and if it is determined that the column entry is less than the row entry, interchanging the column entry and the row entry. The second procedure comprises the following steps: selecting the complement of the multiplicand as the column entry and a complement of the multiplicator as the row entry, and determining whether the column entry is greater than or equal to the row entry; if it is determined that the column entry is greater than or equal to the row entry, keeping the column entry and the row entry; and if it is determined that the column entry is less than the row entry, interchanging the column entry and the row entry.

In another embodiment, a k-cluster residue number system comprises a processor and memory coupled to the processor. The processor is used to generate an addition and subtraction look-up table comprising 2mᵢ cells for recording values from zero to (mᵢ−1) in an ascending order twice, retrieving a value recorded in a cell at position Q of the addition and subtraction look-up table when performing an addition operation on two integers A and B, and retrieving a value recorded in a cell at position R of the addition and subtraction look-up table when subtracting an integer X by an integer Y. Where mᵢ is a coprime integer of a modular set of the k-cluster residue number system, Q=((A mod mᵢ)+(B mod mᵢ)), R=(X mod mi)−(Y mod mi)=(X mod mi)+(mi−(Y mod mi))=rx+(mi−ry)=(rx+ry′), rx is equal to (X mod mᵢ), ry is equal to (Y mod mᵢ), and ry′ is equal to (mᵢ−(Y mod mᵢ)).

In another embodiment, a k-cluster residue number system comprises a processor and a memory coupled to the processor. The processor is used to generate a multiplication look-up table for a coprime integer mᵢ of a modular set of the k-cluster residue number system, and perform a multiplication operation on a multiplicand and a multiplicator using the multiplication look-up table. The coprime integer mᵢ is not 2, and the multiplication look-up table is composed of S cells,

$$S = ( \frac{{m}_{i}^{2} - 1}{4} ) .$$

The multiplication operation comprises determining whether a complement of the multiplicand is greater than or equal to the multiplicator; if it is determined that the complement of the multiplicand is greater than or equal to the multiplicator, performing the first procedure; if it is determined that the complement of the multiplicand is less than the multiplicator, performing a second procedure; and retrieving a value from the multiplication look-up table as a product of the multiplicand and the multiplicator according to a column entry and a row entry. The first procedure comprises the following steps: selecting the multiplicand as the column entry and the multiplicator as the row entry, and determining whether the column entry is greater than or equal to the row entry; if it is determined that the column entry is greater than or equal to the row entry, keeping the column entry and the row entry; and if it is determined that the column entry is less than the row entry, interchanging the column entry and the row entry. The second procedure comprises the following steps: selecting the complement of the multiplicand as the column entry and a complement of the multiplicator as the row entry, and determining whether the column entry is greater than or equal to the complement of the row entry; if it is determined that the column entry is greater than or equal to the row entry, keeping the column entry and the row entry; and if it is determined that the column entry is less than the row entry, interchanging the column entry and the row entry.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a k-cluster residue number system (k-RNS) according to an embodiment of the present invention.

FIG. 2 to FIG. 4 are illustrated to explain how the processor in FIG. 1 generates the addition and subtraction look-up table.

FIG. 5 shows a multiplication look-up table according to an embodiment of the present invention.

FIG. 6 is a flow chart when the processor in FIG. 1 retrieves data from the multiplication look-up table in FIG. 5.

FIG. 7 and FIG. 8 show a temporary multiplication look-up table and are used to explain how the processor in FIG. 1 generates the multiplication look-up table stored in the memory.

FIG. 9 shows the multiplication look-up table in FIG. 1 when the modular set of the k-RNS includes 7.

FIG. 10 is a flow chart when the processor in FIG. 1 retrieves data from one of the multiplication look-up tables.

### DETAILED DESCRIPTION

To represent an n-bit integer and its negative using a k-cluster residue number system (k-RNS), it first defines a modular set of P coprime integers as (m₀, m₁, . . . , mₚ) where a dynamic range is generated according to the product of the modular set (m₀, m₁, . . . , mₚ). For example, when a modular set of 3 coprime integers is chosen to be (2^{n/2}−1, 2, 2^{n/2}+1) , the dynamic range is set to [−(2ⁿ−1), (2ⁿ−2)]. The modular set is not limited to 3 coprime integers.

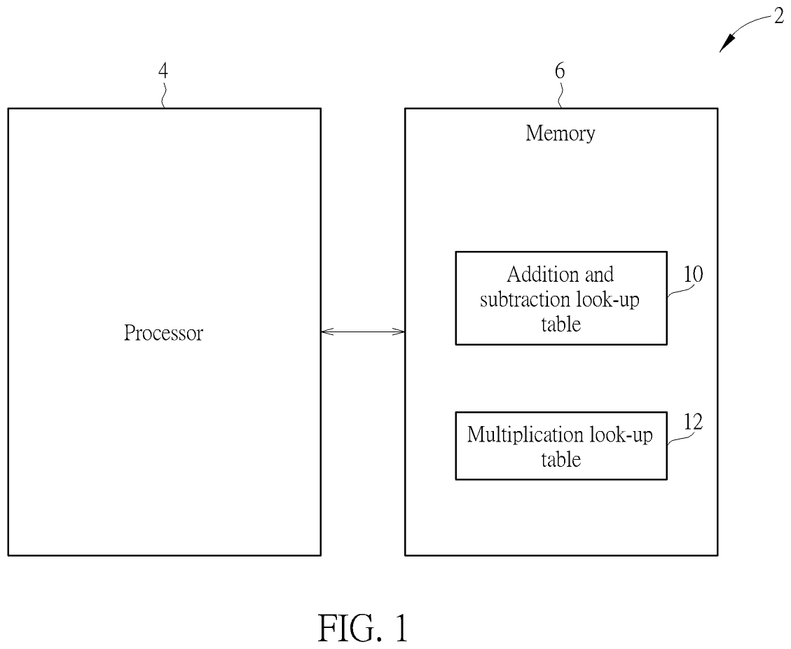

FIG. 1 shows a k-cluster residue number system (k-RNS) 2 according to an embodiment of the present invention. The k-RNS 2 may comprise a processor 4, and a memory 6 coupled to the processor 4. The processor 4 is used to generate an addition and subtraction look-up table 10 and a multiplication look-up table 12. Memory 6 is used to store the addition and subtraction look-up table 10 and the multiplication look-up table 12.

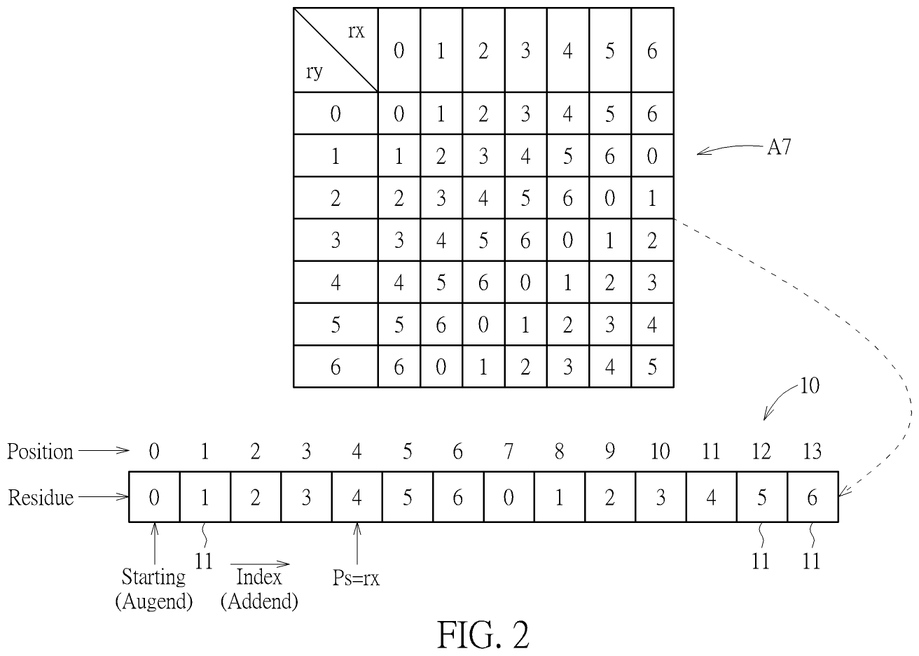

Processor 4 uses the addition and subtraction look-up table 10 to perform addition operations and subtraction operations. FIG. 2 to FIG. 4 are illustrated to explain how processor 4 generates the addition and subtraction look-up table 10. According to the division algorithm, the following equation (4) in an integral domain could be transformed into the following equation (5) in a remainder domain:

Z=X+Y (4)

rz=rx+ry (5)
where:
X, Y, and Z are three integers;
rx is equal to (X mod mᵢ);
ry is equal to (Y mod mᵢ);
rz is equal to (Z mod mᵢ); and
mᵢ is selected from the modular set of the k-cluster residue number system 2.

In the embodiment, one modulus of the modular set selected by processor 4 is 7. However, the present invention is not limited thereto. The selected modulus could be other coprime integers of the modular set. The addition and subtraction look-up table 10 is composed of 14 (i.e., 2×7) cells 11 for recording values from zero to 6 in an ascending order twice. The addition and subtraction look-up table 10 is a one-dimensional linear array, which is simplified from a traditional two-dimensional addition look-up table A7 for addition operations based on modulus 7. The traditional addition look-up table A7 comprises 49 (i.e., 7×7) cells, more than fourteen cells 11 of the addition and subtraction look-up table 10. Each of the cells 11 is used to store a residue when an addition operation on two remainders rx and ry or two integers X and Y is performed, where rx=(X mod 7) and ry=(Y mod 7). The addition look-up table A7 is transformed to the addition and subtraction look-up table 10 based on the periodic behaviors of the modulo. As shown in FIG. 2, the sum stored in each cell of the addition look-up table A7 differs by one from the adjacent one. Therefore, the addition look-up table A7 could be simplified and transformed into the addition and subtraction look-up table 10. The remainder rx (i.e., the augend) may be used as the table entry, and the remainder ry (i.e., the addend) maybe used as the table index in ascending order to retrieve the result. In the embodiment, a start position Ps would be set to be equal to the augend rx, and the start position Ps would be shifted according to the addend ry. In detail, when the addition operation on two integers X and Y is performed, a value recorded in cell 11 at position Q of the addition and subtraction look-up table 10 is retrieved as the result of the addition operation, where Q=((X mod mᵢ)+(Y mod mᵢ)), and mᵢ is the modulus. Since mᵢ=7, (X mod mᵢ)=(X mod 7)=rx, and (Y mod mᵢ)=(Y mod 7)=ry, Q=(rx+ry). For example, when rx=4 and ry=5, the start position Ps is set to 4, and the Ps is shifted to 5, the value recorded in cell 11 at position 9 (i.e., 4−5=9) would be retrieved as the result of (rx+ry).

Similarly, according to the subtraction algorithm, the following equation (6) in the integral domain could be transformed into the following equation (7) in the remainder domain:

Z=X−Y (6)

rz=rx−ry (7)

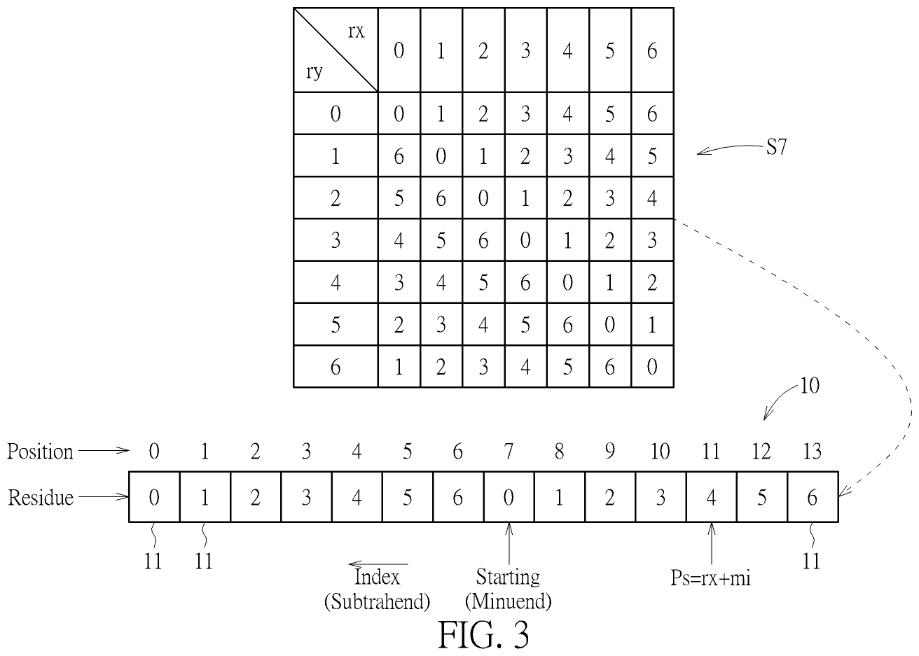

Therefore, the addition and subtraction look-up table 10 could be used not only for addition operations but also for subtraction operations since the addition and subtraction look-up table 10 could be obtained by simplifying a traditional subtraction look-up table S7. The traditional subtraction look-up table S7 also comprises 49 (i.e., 7×7) cells, more than fourteen cells 11 of the addition and subtraction look-up table 10. Each of the cells 11 is used to store a residue when the remainder rx is subtracted by the remainder ry. The subtraction look-up table S7 is transformed to the addition and subtraction look-up table 10 based on periodic behaviors of the modulo. As shown in FIG. 3, the value stored in each cell 11 of the subtraction look-up table S7 differs by one from the adjacent one. Therefore, the subtraction look-up table S7 could be simplified and transformed into the addition and subtraction look-up table 10. A sum of the remainder rx (i.e., the minuend) and the modulus mi may be used as the table entry, and the remainder ry (i.e., the subtrahend) may be used as the table index in descending order to retrieve the result. In the embodiment, a start position Ps would be set to be equal to the sum of the minuend rx and the modulus mᵢ, and the start position Ps would be shifted according to the subtrahend ry. In detail, when the addition operation on two integers X and Y is performed, a value recorded in cell 11 at position R of the addition and subtraction look-up table 10 is retrieved as the result of the subtraction operation, where R=(mᵢ+(X mod mᵢ)−(Y mod mᵢ)). Since mᵢ=7, (X mod mᵢ)=(X mod 7)=rx, and (Y mod mᵢ)=(Y mod 7)=ry, R=(mᵢ+rx−ry). For example, when we subtract 5 with 4, rx=5 and ry=4, the table entry becomes (5+7)=12, where 7 is equal to mi, then, it shifts to the left by 4, the value recorded in the cell 11 at position 8 is defined as 1, it matches the result of (rx−ry)=1.

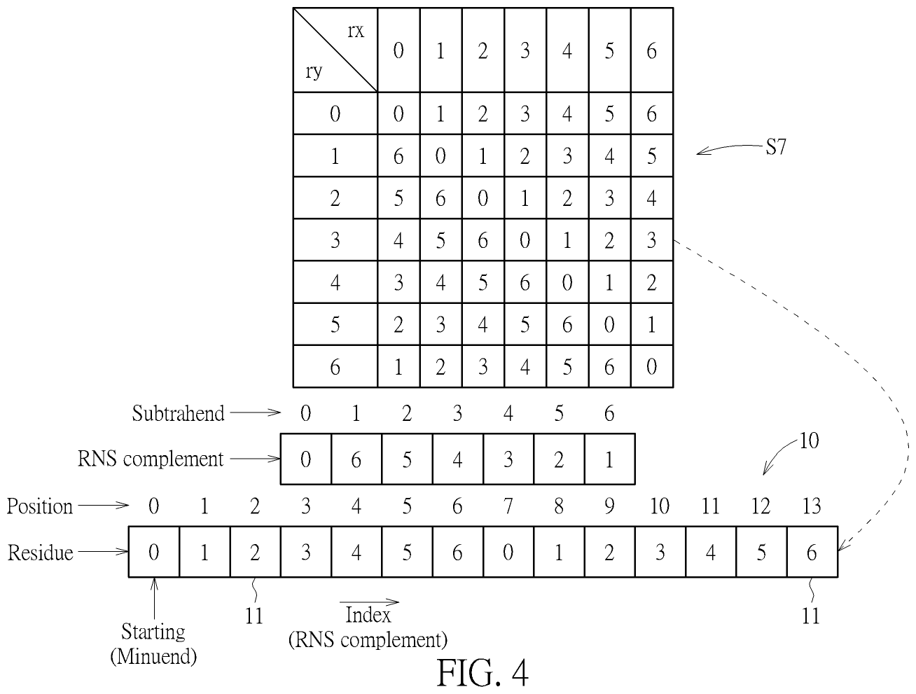

In another embodiment of the present invention, when processor 4 subtracts the integer X by the integer Y, processor 4 retrieves the value from the addition and subtraction look-up table 10 according to the complement ry′ of the remainder ry and the remainder rx (i.e., the minuend). Referring to FIG. 4, in the embodiment, the remainder rx (i.e., the minuend) may be used as the table entry, and the complement ry′ may be used as the index in ascending order to retrieve the result. In detail, when the processor 4 subtracts the integer X by the integer Y, the processor 4 retrieves a value recorded in a cell 11 at position R of the addition and subtraction look-up table 10, where R=(X mod mi)−(Y mod mi)=(X mod mi)+(mi−(Y mod mi))=rx+(mi−ry)=rx−ry′ and ry′ is the complement of the remainder ry (i.e., ry′=mᵢ−ry). The complement ry′ may be obtained according to a complement table. For example, when mᵢ=7, a complement table can be illustrated as follows:

| ry | 0 | 1 | 2 | 3 | 4 | 5 | 6 |
|---|---|---|---|---|---|---|---|
| ry′ | 0 | 6 | 5 | 4 | 3 | 2 | 1 |

Since R=(rx+ry′), the start position Ps would be set to be rx of the addition and subtraction look-up table 10, then it is shifted according to the complement ry′. For example, when we subtract 5 with 4, rx=5 and ry=4, the table entry becomes=5, the complement of ry=4 is ry′=3, it shifts to the right by 3, the value recorded in cell 11 at position 8 is defined as 1, it matches the result of (rx−ry)=1.

Therefore, the two-dimensional addition look-up table A7 and the two-dimensional subtraction look-up table S7 could be simplified and transformed into the addition and subtraction look-up table 10, which is a one-dimensional linear array. The addition and subtraction look-up table 10 is used by processor 4 when processor 4 performs an addition operation or a subtraction operation when the modulus mᵢ=7. Since the modulus mᵢ may be an integer other than 7, processor 4 could generate corresponding addition and subtraction look-up tables for other coprime integers of the modular set.

In detail, if the k-RNS 2 uses P coprime integers to define its modular set as (m₁, . . . , 2, . . . , mₚ), the processor 4 generates a corresponding addition and subtraction look-up table for each coprime integer not equal to 2. If the coprime integer is mᵢ, its corresponding addition and subtraction look-up table is composed of 2mᵢ cells 11 for recording values from zero to (mᵢ−1) in an ascending order twice. When processor 4 performs an addition operation on two integers X and Y, processor 4 retrieves a value recorded in cell 11 at position Q of the addition and subtraction look-up table 10, where Q=((X mod mᵢ)+(Y mod mᵢ))=(rx+ry). When processor 4 subtracts the integer X by the integer Y, processor 4 retrieves a value recorded in cell 11 at position R of the addition and subtraction look-up table 10, where R=(X mod mi)−(Y mod mi)=(X mod mi)+(mi−(Y mod mi))=rx+ry′, and ry′ is the complement of the remainder ry (i.e., ry′=mᵢ−ry). According to the subtraction algorithm, the following equation (8) in the integral domain could be transformed into the following equation (9) in the remainder domain:

Z=X×Y (8)

rz=(rx×ry) (9)
where:
X, Y, and Z are three integers;
rx is equal to (X mod mᵢ);
ry is equal to (Y mod mᵢ);
rz is equal to (Z mod mᵢ); and
mᵢ is selected from the modular set of the k-cluster residue number system 2.

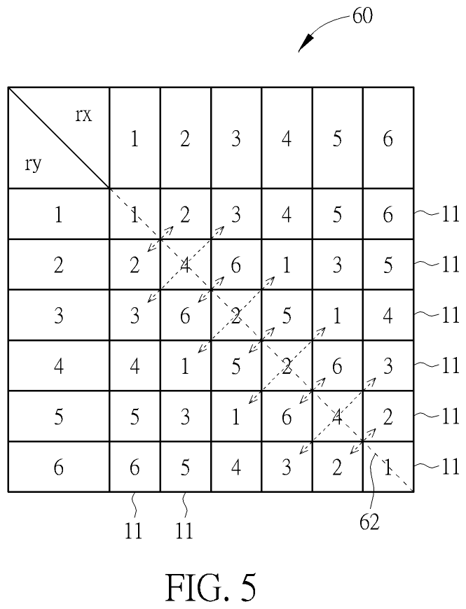

FIG. 5 shows a multiplication look-up table 60 according to an embodiment of the present invention. A product of two integers X and Y would be zero if one of two integers X and Y is zero, so all cells whose value is equal to zero in a multiplication look-up table could be eliminated. Accordingly, the data amount of the temporary multiplication look-up table 60 could be presented as the following equation (10):

$$M e m 2 = {\sum }_{i = 0}^{n} {( {m}_{i} - 1 )}^{2} \times {b}_{i} \qquad ( 10 )$$

where:
Mem2 is the data amount of the temporary multiplication look-up table 60;
mᵢ is the i^{th} modulus; and
bᵢ is the number of bits of the i^{th} modulus.

According to equations (2) and (10), the lookup table size is reduced from

$${\sum }_{i = 0}^{n} {m}_{i}^{2}$$

to

$${\sum }_{i = 0}^{n} {( {m}_{i} - 1 )}^{2}$$

as compared with the prior art. Moreover, according to the multiplication commutative rule, the order of the multiplicand and multiplicator can be exchanged. Therefore, the products of the temporary multiplication look-up table 60 could be mirrored along a Top-Left and Bottom-Right (TL/BR) diagonal line 62, as shown in FIG. 5.

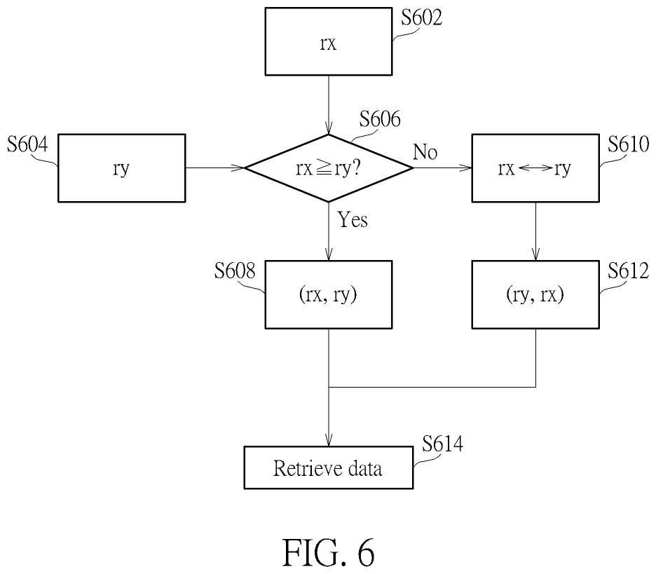

FIG. 6 is a flow chart when processor 4 in FIG. 1 retrieves data from the multiplication look-up table 60 in FIG. 5. Processor 4 first receives rx (Step S602) and ry (Step S604), then compares rx with ry (Step S606). If rx is greater than or equal to ry, processor 4 keeps rx and ry without changes (Step S608), so that rx is selected as a column entry and ry is selected as a row entry to access the multiplication look-up table 60; otherwise, the processor 4 interchanges rx and ry positions for memory location access (Steps S610 and S612), so that ry is selected as a column entry and rx is selected as a row entry to access the multiplication look-up table 60. In Step S608, rx is selected as a column entry and ry is selected as a row entry. In Step S612, ry is selected as a column entry and rx is selected as a row entry to access the multiplication look-up table 60. In Step S614, processor 4 retrieves data from the multiplication look-up table 60 according to the column entry and row entry. This approach can reduce the memory size by half.

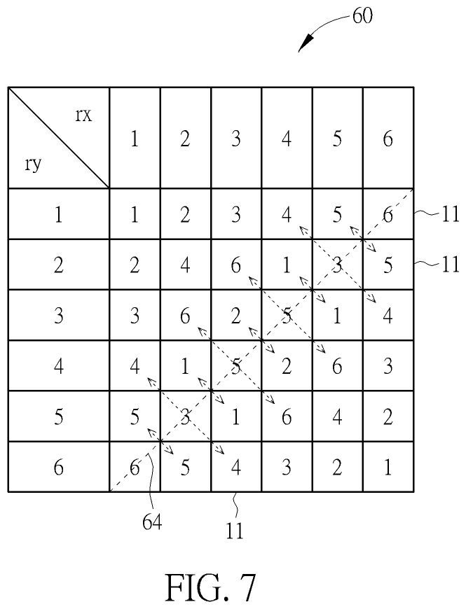

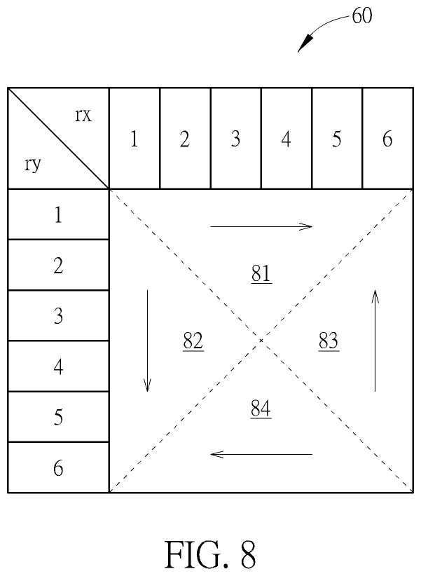

FIG. 7 and FIG. 8 show a temporary multiplication look-up table 60 and are used to explain how the processor in FIG. 1 generates one of the multiplication look-up tables 12 stored in memory 6. In the embodiment, the k-RNS 2 offers additional mirror property based on periodic behaviors of the modulo, the products of the temporary multiplication look-up table 60 could be mirrored along with a Top-Right and Bottom-Left (TR/BL) diagonal line 64, as shown in FIG. 7. Therefore, the temporary multiplication look-up table 60 can be partitioned into four identical regions 81, 82, 83 and 84, as shown in FIG. 8, to reduce the table size. Accordingly, the lookup table size for multiplication operations may be further reduced from

$${\sum }_{i = 0}^{n} {( {m}_{i} - 1 )}^{2}$$

to

$${\sum }_{i = 0}^{n} ( {m}_{i}^{2} - 1 ) / 4.$$

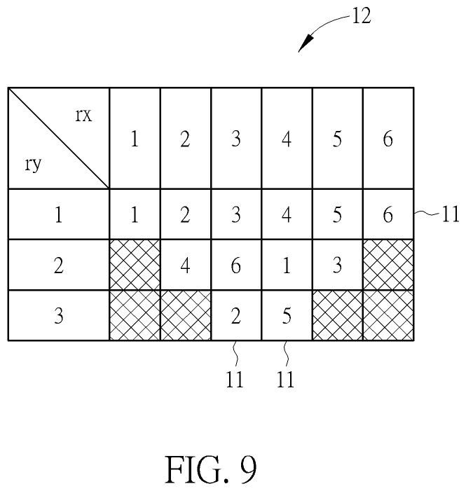

For example, the multiplication look-up table 12 has twelve cells 11 while the temporary multiplication look-up table 60 has thirty-six cells 11. Therefore, the lookup table size for multiplication operations is further reduced. Due to the mirror property and the periodic behaviors of the modulo, the four identical regions 81, 82, 83, and 84 could be simplified as a multiplication look-up table 12, as shown in FIG. 9. The multiplication look-up table 12 is corresponding to modulus 7 (i.e., mᵢ=7). Processor 4 may generate a multiplication look-up table 12 for each coprime integer of the modular set, and a multiplication look-up table for the coprime integer mᵢ is composed of S cells 11, where

$$S = ( \frac{{m}_{i}^{2} - 1}{4} ) .$$

Accordingly, the data amount of the multiplication look-up table 12 could be presented as the following equation (11):

$$M e m 3 = {\sum }_{i = 0}^{n} ( \frac{{m}_{i}^{2} - 1}{4} ) \times {b}_{i} \qquad ( 11 )$$

where:
Mem3 is the data amount of the multiplication look-up table 12;
mᵢ is the i^{th} modulus; and
bᵢ is the number of bits of the i^{th} modulus.

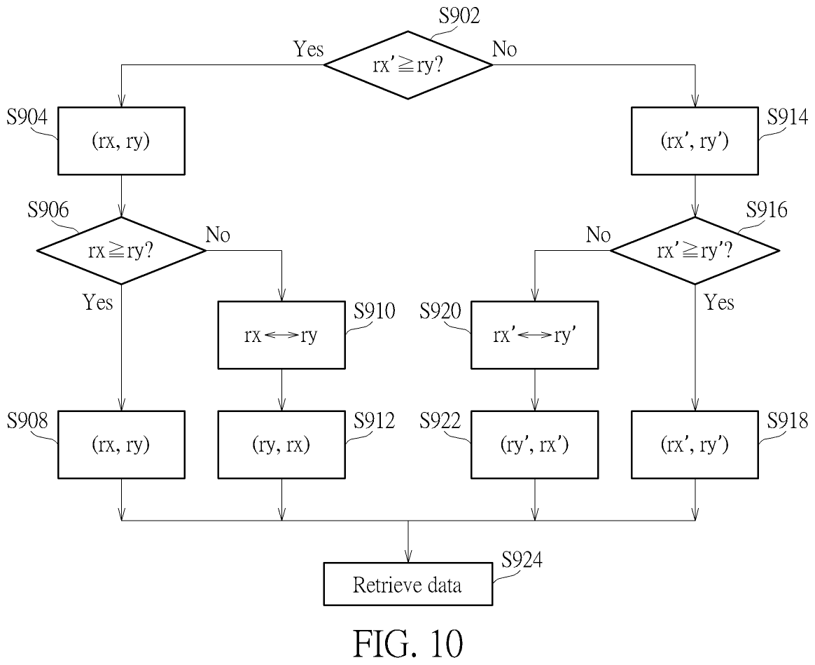

When processor 4 performs a multiplication operation on the two integers X and Y, processor 4 would perform the procedure shown in FIG. 10. To access the correct stored product location, processor 4 selects the multiplicand (rx) as the lookup table column entry and the multiplicator (ry) as the row entry, then modifies or keeps the two entries to access the product stored in a different region. In detail, when processor 4 performs a multiplication operation on a multiplicand rx and a multiplicator ry using the multiplication look-up table 12, the multiplication operation may comprise the following steps:

Step S902: determine whether a complement rx′ of the multiplicand rx is greater than or equal to the multiplicator ry; if it is determined that the complement rx′ of the multiplicand rx is greater than or equal to the multiplicator ry, go to Step S904; otherwise, go to Step S914;

Step S904: select the multiplicand rx as the column entry and the multiplicator ry as the row entry;

Step S906: determine whether the column entry (rx) is greater than or equal to the row entry (ry); if it is determined that the column entry (rx) is greater than or equal to the row entry (ry), go to Step 908; otherwise, go to Step S910;

Step 908: keep the column entry and the row entry; go to Step 924

Step 910: interchange the column entry and the row entry;

Step 912: ry is selected as the column entry and rx is selected as the row entry; go to Step S924

Step S914: select the complement rx′ of rx as the column entry and the complement ry′ of the multiplicator ry as the row entry;

Step S916: determine whether the column entry (rx′) is greater than or equal to the row entry (ry′); if it is determined that the column entry (rx′) is greater than or equal to the row entry (ry′), go to Step S918; otherwise go to step S920;

Step S918: keep the column entry (rx′) and the row entry (ry′); Go to Step S924

Step S920: interchange the column entry (rx′) and row entry (ry′);

Step S922: the complement ry′ of ry is selected as the column entry and complement rx′ of rx is selected as the row entry; go to Step 924

Step 924: Retrieve a value from the multiplication look-up table 12 as a product of the multiplicand and the multiplicator according to the column entry and the row entry.

Briefly, processor 4 changes the column entry from rx to its RNS complement rx′, where rx′=(mᵢ−rx), then processor 4 compares rx with ry (step S902). If rx′ is less than ry, then both the row and column entries are changed into their residue complement (step S114, where rx′=(mᵢ−rx) and ry′=(mᵢ−ry)), otherwise keeping rx and ry without change (step S904). After that, processor 4 compares the row (rx) and column (ry) entries. If rx is less than ry, then rx and ry are interchanged (rx⇄ry) for table access.

For example, when mᵢ=7, X=10, and Y=19, rx=3, ry=5, rx′=7−3=4, ry′=7−5=2 According to the above approach, the column entry is rx′=4, and the row entry is ry′=2. Therefore, when processor 4 performs a multiplication operation on X and Y, processor 4 would retrieve the value recorded in cell 11 at the 4^{th} column and 2^{nd} row of the multiplication look-up table 12 as the product of the modulo multiplication. The product of X=10 and Y=19 is 190, where the residue |190|₇=1. It is consistent with the value: 1 stored in 4^{th} column and 2^{rd} row. In another example, when mᵢ=7, X=11, and Y=15, rx=4, ry=1, rx′=7−4=3, ry′=7−1=6, the column entry is rx=4, and the row entry is ry=1. Therefore, when processor 4 performs a multiplication operation on X and Y (i.e., 11×15), where the residue |165|₇=4, processor 4 would retrieve the value: 4 recorded in cell 11 at the 4^{th} column and 1^{st} row of the multiplication look-up table 12 as the product of the multiplication.

In the k-cluster residue number system 2, since the addition and subtraction look-up table 10 and the multiplication look-up table 12 have compressed size, the required size of the memory 6 for storing look-up tables for addition, subtraction, and multiplication operations could be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing addition and subtraction operations in a k-cluster residue number system, the method comprising:
generating an addition and subtraction look-up table comprising 2mᵢ cells for recording values from zero to (mᵢ−1) in an ascending order twice, wherein mᵢ is a coprime integer of a modular set of the k-cluster residue number system;
storing the addition and subtraction look-up table in a memory of the k-cluster residue number system;
retrieving a value recorded in a cell at position Q of the addition and subtraction look-up table when performing an addition operation on two integers A and B, where Q=((A mod mᵢ)+(B mod mᵢ)); and
retrieving a value recorded in a cell at position R of the addition and subtraction look-up table when subtracting an integer X by an integer Y, where R=(X mod mi)−(Y mod mi)=(X mod mi)+(mi−(Y mod mi))=rx+(mi−ry)=rx+ry′, rx is equal to (X mod mᵢ), ry is equal to (Y mod mᵢ), and ry′ is equal to (mᵢ−(Y mod mᵢ)).

2. The method of claim 1 further comprising:
generating a multiplication look-up table for the coprime integer mᵢ, wherein the coprime integer mᵢ is not 2, and the multiplication look-up table is composed of S cells, where
$$S = ( \frac{{m}_{i}^{2} - 1}{4} ) ;$$
and
storing the multiplication look-up table in the memory.

3. The method of claim 2 further comprising:
performing a multiplication operation on a multiplicand and a multiplicator using the multiplication look-up table, comprising:
determining whether a complement of the multiplicand is greater than or equal to the multiplicator;
if it is determined that the complement of the multiplicand is greater than or equal to the multiplicator, perform the following steps:
selecting the multiplicand as a column entry and the multiplicator as a row entry, and determining whether the column entry is greater than or equal to the row entry;
if it is determined that the column entry is greater than or equal to the row entry, keeping the column entry and the row entry; and
if it is determined that the column entry is less than the row entry, interchanging the column entry and the row entry;
if it is determined that the complement of the multiplicand is less than the multiplicator, perform the following steps:
selecting the complement of the multiplicand as the column entry and a complement of the multiplicator as the row entry, and determining whether the column entry is greater than or equal to the complement of the row entry;
if it is determined that the column entry is greater than or equal to the complement of the row entry, keeping the column entry and the row entry; and
if it is determined that the column entry is less than the row entry, interchanging the column entry and the row entry; and
retrieving a value from the multiplication look-up table as a product of the multiplicand and the multiplicator according to the column entry and the row entry.

4. A method for performing multiplication operations in a k-cluster residue number system, the method comprising:
generating a multiplication look-up table for a coprime integer mᵢ of a modular set of the k-cluster residue number system, wherein the coprime integer mᵢ is not 2, the multiplication look-up table is composed of S cells,
$$S = ( \frac{{m}_{i}^{2} - 1}{4} ) ;$$
and
storing the multiplication look-up table in a memory of the k-cluster residue number system; and
performing a multiplication operation on a multiplicand and a multiplicator using the multiplication look-up table, comprising:
determining whether a complement of the multiplicand is greater than or equal to the multiplicator;
if it is determined that the complement of the multiplicand is greater than or equal to the multiplicator, perform the following steps:
selecting the multiplicand as a column entry and the multiplicator as a row entry, and determining whether the column entry is greater than or equal to the row entry;
if it is determined that the column entry is greater than or equal to the row entry, keeping the column entry and the row entry; and
if it is determined that the column entry is less than the row entry, interchanging the column entry and the row entry;
if it is determined that the complement of the multiplicand is less than the multiplicator, perform the following steps:
selecting the complement of the multiplicand as the column entry and a complement of the multiplicator as the row entry, and determining whether the column entry is greater than or equal to the complement of the row entry;
if it is determined that the column entry is greater than or equal to the complement of the row entry, keeping the column entry and the row entry; and
if it is determined that the column entry is less than the row entry, interchanging the column entry and the row entry; and
retrieving a value from the multiplication look-up table as a product of the multiplicand and the multiplicator according to the column entry and the row entry.

5. The method of claim 4 further comprises:
generating an addition and subtraction look-up table comprising 2mᵢ cells for recording values from zero to (mᵢ−1) in an ascending order twice; and
storing the addition and subtraction look-up table in the memory of the k-cluster residue number system.

6. The method of claim 5 further comprises:
retrieving a value recorded in a cell at position Q of the addition and subtraction look-up table when performing an addition operation on two integers A and B, where Q=((A mod mᵢ)+(B mod mᵢ)).

7. The method of claim 5 further comprises:
retrieving a value recorded in a cell at position R of the addition and subtraction look-up table when subtracting an integer X by an integer Y, where R=(X mod mi)−(Y mod mi)=(X mod mi)+(mi−(Y mod mi))=rx+(mi−ry)=(rx+ry′), rx is equal to (X mod mᵢ), ry is equal to (Y mod mᵢ), and ry′ is equal to (mᵢ−(Y mod mᵢ)).

8. A k-cluster residue number system comprising:
a processor configured to:
generate an addition and subtraction look-up table comprising 2mᵢ cells for recording values from zero to (mᵢ−1) in an ascending order twice, wherein mᵢ is a coprime integer of a modular set of the k-cluster residue number system;
retrieve a value recorded in a cell at position Q of the addition and subtraction look-up table when performing an addition operation on two integers A and B, where Q=((A mod mᵢ)+(B mod mᵢ)); and
retrieve a value recorded in a cell at position R of the addition and subtraction look-up table when subtracting an integer X by an integer Y, where R=(X mod mi)−(Y mod mi)=(X mod mi)+(mi−(Y mod mi))=rx+(mi−ry)=(rx+ry′), rx is equal to (X mod mᵢ), ry is equal to (Y mod mᵢ), and ry′ is equal to (mᵢ−(Y mod mᵢ)); and
a memory coupled to the processor and configured to store the addition and subtraction look-up table.

9. The k-cluster residue number system of claim 8, wherein the processor is further configured to:
generate a multiplication look-up table for the coprime integer mᵢ, wherein the coprime integer mᵢ is not 2, and the multiplication look-up table is composed of S cells, where
$$S = ( \frac{{m}_{i}^{2} - 1}{4} ) ;$$
and
store the multiplication look-up table in the memory.

10. The k-cluster residue number system of claim 9, wherein the processor is further configured to:
perform a multiplication operation on a multiplicand and a multiplicator using the multiplication look-up table by performing the following steps:
determining whether a complement of the multiplicand is greater than or equal to the multiplicator;
if it is determined that the complement of the multiplicand is greater than or equal to the multiplicator, perform the following steps:
selecting the multiplicand as a column entry and the multiplicator as a row entry, and determining whether the column entry is greater than or equal to the row entry;
if it is determined that the column entry is greater than or equal to the row entry, keeping the column entry and the row entry; and
if it is determined that the column entry is less than the row entry, interchanging the column entry and the row entry;
if it is determined that the complement of the multiplicand is less than the multiplicator, perform the following steps:
selecting the complement of the multiplicand as the column entry and a complement of the multiplicator as the row entry, and determining whether the column entry is greater than or equal to the complement of the row entry;
if it is determined that the column entry is greater than or equal to the complement of the row entry, keeping the column entry and the row entry; and
if it is determined that the column entry is less than the row entry, interchanging the column entry and the row entry; and
retrieving a value from the multiplication look-up table as a product of the multiplicand and the multiplicator according to the column entry and the row entry.

11. A k-cluster residue number system, comprising:
a processor configured to:
generate a multiplication look-up table for a coprime integer mᵢ of a modular set of the k-cluster residue number system, wherein the coprime integer mᵢ is not 2, and the multiplication look-up table is composed of S cells,
$$S = ( \frac{{m}_{i}^{2} - 1}{4} ) ;$$
and
perform a multiplication operation on a multiplicand and a multiplicator using the multiplication look-up table by performing the following steps:
determining whether a complement of the multiplicand is greater than or equal to the multiplicator;
if it is determined that the complement of the multiplicand is greater than or equal to the multiplicator, perform the following steps:
selecting the multiplicand as a column entry and the multiplicator as a row entry, and determining whether the column entry is greater than or equal to the row entry;
if it is determined that the column entry is greater than or equal to the row entry, keeping the column entry and the row entry; and
if it is determined that the column entry is less than the row entry, interchanging the column entry and the row entry;
if it is determined that the complement of the multiplicand is less than the multiplicator, perform the following steps:
selecting the complement of the multiplicand as the column entry and a complement of the multiplicator as the row entry, and determining whether the column entry is greater than or equal to the complement of the row entry;
if it is determined that the column entry is greater than or equal to the complement of the row entry, keeping the column entry and the row entry; and
if it is determined that the column entry is less than the row entry, interchanging the column entry and the row entry; and
retrieving a value from the multiplication look-up table as a product of the multiplicand and the multiplicator according to the column entry and the row entry; and
a memory coupled to the processor and configured to store the multiplication look-up table.

12. The k-cluster residue number system of claim 11, wherein the processor is further configured to:
generate an addition and subtraction look-up table comprising 2mᵢ cells for recording values from zero to (mᵢ−1) in an ascending order twice; and
store the addition and subtraction look-up table in the memory of the k-cluster residue number system.

13. The k-cluster residue number system of claim 12, wherein the processor is further configured to:
retrieve a value recorded in a cell at position Q of the addition and subtraction look-up table when performing an addition operation on two integers A and B, where Q=((A mod mᵢ)+(B mod mᵢ)).

14. The k-cluster residue number system of claim 12, wherein the processor is further configured to:
retrieve a value recorded in a cell at position R of the addition and subtraction look-up table when subtracting an integer X by an integer Y, where R=(X mod mi)−(Y mod mi)=(X mod mi)+(mi−(Y mod mi))=rx+(mi−ry)=(rx+ry′), rx is equal to (X mod mᵢ), ry is equal to (Y mod mᵢ), and ry′ is equal to (mᵢ−(Y mod mᵢ)).
